(19) United States
(12) Patent Application Publication
(10) Pub. No.: US 2007/0232056 A1
(43) Pub. Date: Oct. 4, 2007

(54) Semiconductor device and method for manufacturing the same

(75) Inventors: Nobukatsu Saitou, Kawasaki (JP); Tadashi Uno, Kawasaki (JP); Masashi Kano, Kawasaki (JP); Yoshihiro Matsuoka, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/504,680

(22) Filed: Aug. 16, 2006

(30) Foreign Application Priority Data
Mar. 30, 2006 (JP) 2006-095737

(51) Int. Cl. H01L 21/4763

(52) U.S. Cl. 438/618

(57) ABSTRACT

It is an object of the present invention to provide a semiconductor device with high performance and reliability, in which peeling off of interconnection layers or conductive layers due to thermal stress developed during packaging of a semiconductor substrate is suppressed, and thus electrical break down is prevented and an efficient method for manufacturing the semiconductor device. The semiconductor device of the present invention is characterized by having a semiconductor substrate, an interconnection layer 12, a first conductive layer 15, an interlayer insulating film 16 and a second conductive layer 17. The method for manufacturing the semiconductor device of the present invention is characterized by containing at least forming an interconnection layer, forming a first conductive layer, forming an interlayer insulating film and forming a second conductive layer so as to be electrically connected to the first conductive layer.

### CROSS-REFERENCE TO RELATED APPLICATIONS

This application is based upon and claims the benefits of the priority from the prior Japanese Patent Application No. 2006-095737, filed on Mar. 30, 2006, the entire contents of which are incorporated herein by reference.

### BACKGROUND OF THE INVENTION

1. Field of the Invention

The present invention relates to a semiconductor device with high performance and reliability, in which peeling off of interconnection layers or conductive layers due to thermal stress developed during packaging of a semiconductor substrate is suppressed, and thus electrical break down is prevented, and an efficient method for manufacturing the semiconductor device.

2. Description of the Related Art

Attempts have been made in recent years to achieve downsizing and greater packaging density of semiconductor devices, with the trend moving toward for thinner, smaller electronic devices. Against this background, wafer level packaging has been proposed, which aims to achieve downsizing by minimizing the semiconductor device to the size of a semiconductor element (chip) as much as possible. The wafer-level package is one in which semiconductor chips are packaged on the wafer prior to singulation, thereby enabling real chip size packaging at low cost compared to conventional packaging. Meanwhile, high pin-count and miniaturization of the semiconductor device resulted from the increase in density leads to narrow pitches between adjacent external terminals. For this reason, wafer level packaging also adopts a configuration that uses bumps (electrodes) rather than pillar-shaped bumps, allowing relatively many external terminals to be formed in a small space. (see International Publication No. WO 02/035602 brochure).

The composition of the semiconductor device in which bumps are disposed, for example, has a semiconductor substrate 1, a multilayered interconnection layer 2 formed over the semiconductor substrate 1, a conductive layer 3 (electrode pad) formed over the interconnection layer 2 and a resin film 4 which covers the vicinity of an outer periphery of the conductive layer 3, as shown in FIG. 34. On the surface of the conductive layer 3 which is exposed from the resin film 4, a barrier metal layer 5 is formed and a bump 6 is disposed on the conductive layer 3 through the barrier metal layer 5 as an external terminal.

In the method for forming bumps disclosed in International Publication No. WO O_{2/035602}, for example, first, a resist film is formed over the conductive layer side of the semiconductor substrate surface, on which the interconnection layer and the conductive layer are disposed in this order. The areas other than the conductive layer are coated with the resist film as a result of exposure and development of the resist film. A barrier metal layer made of Ni, etc. is formed over the conductive layer, which is exposed from the resist film, by sputtering. And then a solder plate is deposited on the barrier metal layer by injection from solder jet nozzles or by dipping in a plating solution. Finally, bumps are formed over the conductive layer by removing the barrier metal layer on the areas other than the connection area of bumps by etching and peeling the resist layer with use of a peeling liquid.

During packaging of a semiconductor chip (FC-BGA substrate) in which the bumps are disposed, the bumps are melted by heating while adding a constant load to the bumps and the semiconductor chip is connected to the opposite substrate by welding with pressure in a molten state.

However, there is a problem that the multilayered interconnection of interconnection layers or conductive layer (electrode pads) is likely to be peeled off by stress on the semiconductor chip side due to thermal stress generated from the thermal contraction of the opposite substrate, which is greater as compared to that of the semiconductor chip. Moreover, because a lead-free material with a high degree of hardness is used for bumps, plastic deformation capacity is low, allowing greater stress on the semiconductor chip side, thereby causing peeling off of interconnection layers and conductive layers.

Therefore, semiconductor devices with high performance and reliability, in which peeling off of interconnection layers or conductive layers due to thermal stress developed during packaging is suppressed, and methods for manufacturing the semiconductor devices have not yet been provided.

It is an object of the present invention to settle foregoing problems and to fulfill the following purposes.

The purpose of the present invention is to provide a semiconductor device with high performance and reliability, in which peeling off of interconnection layers or conductive layers due to thermal stress developed during packaging of a semiconductor substrate is suppressed, and thus electrical break down is prevented, and an efficient method for manufacturing the semiconductor devices.

### SUMMARY OF THE INVENTION

The measures to settle above issues are as follows.

The semiconductor device of the present invention is characterized by having a semiconductor substrate, an interconnection layer formed over the semiconductor substrate, a first conductive layer formed over the interconnection layer, an interlayer insulating film formed over the first conductive layer and a second conductive layer formed over the interlayer insulating film so as to be electrically connected to the first conductive layer.

The semiconductor device has the first conductive layer and the second conductive layer. For this reason, it exhibits greater strength on the conductive layer side during packaging through external terminals such as bumps as compared to the conventional semiconductor device with only one conductive layer, allows diffusion of stress due to thermal stress and suppresses peeling off of conductive layer as well as peeling off of interconnection layer by inhibiting stress on the interconnection layer side. Therefore, the semiconductor device of the present invention is of high performance and reliability and particularly suitable for wafer-level package.

The method for manufacturing the semiconductor device of the present invention is a method for manufacturing aforementioned semiconductor device of the present invention, and it is characterized by containing at least forming an interconnection layer on a semiconductor substrate, forming a first conductive layer on the interconnection layer, forming an interlayer insulating film on the first conductive layer and forming a second conductive layer on the interlayer insulating film so as to be electrically connected to the first conductive layer.

In the method for manufacturing the semiconductor device, the interconnection layer is formed over the semiconductor substrate in the forming step of interconnection layer. The first conductive layer is formed over the interconnection layer in the forming step of first conductive layer. The interlayer insulating film is formed over the first conductive layer in the forming step of interlayer insulating film. The second conductive layer is formed over the interlayer insulating film in the forming step of second conductive layer. As a result, a number of the conductive layers are formed and the strength on the conductive layer becomes greater during packaging through external terminals such as bumps, allowing diffusion of stress due to thermal stress and suppressing peeling off of conductive layer as well as peeling off of interconnection layer by inhibiting stress on the interconnection layer side. Therefore, semiconductor devices with high performance and reliability are manufactured efficiently.

### BRIEF DESCRIPTION OF THE DRAWINGS

FIG. 1 is a cross sectional view showing Example 1 of the semiconductor device of the present invention.

FIG. 2A is a perspective view showing the first and the second conductive layers and vias in Example 1 of the semiconductor device of the present invention.

FIG. 2B is a perspective view showing the first and the second conductive layers and vias in another Example of the method for manufacturing the semiconductor device of the present invention.

FIG. 3 is a first view showing an exemplary method for manufacturing the semiconductor device of the present invention of Example 1.

FIG. 4 is a second view showing an exemplary method for manufacturing the semiconductor device of the present invention of Example 1.

FIG. 5 is a third view showing an exemplary method for manufacturing the semiconductor device of the present invention of Example 1.

FIG. 6 is a fourth view showing an exemplary method for manufacturing the semiconductor device of the present invention of Example 1.

FIG. 7 is a fifth view showing an exemplary method for manufacturing the semiconductor device of the present invention of Example 1.

FIG. 8 is a sixth view showing an exemplary method for manufacturing the semiconductor device of the present invention of Example 1.

FIG. 9 is a seventh view showing an exemplary method for manufacturing the semiconductor device of the present invention of Example 1.

FIG. 10 is an eighth view showing an exemplary method for manufacturing the semiconductor device of the present invention of Example 1.

FIG. 11 is a ninth view showing an exemplary method for manufacturing the semiconductor device of the present invention of Example 1.

FIG. 12 is a tenth view showing an exemplary method for manufacturing the semiconductor device of the present invention of Example 1.

FIG. 13 is a first view showing an exemplary method for manufacturing the semiconductor device of the present invention of Example 2.

FIG. 14 is a second view showing an exemplary method for manufacturing the semiconductor device of the present invention of Example 2.

FIG. 15 is a third view showing an exemplary method for manufacturing the semiconductor device of the present invention of Example 2.

FIG. 16 is a fourth view showing an exemplary method for manufacturing the semiconductor device of the present invention of Example 2.

FIG. 17 is a fifth view showing an exemplary method for manufacturing the semiconductor device of the present invention of Example 2.

FIG. 18 is a sixth view showing an exemplary method for manufacturing the semiconductor device of the present invention of Example 2.

FIG. 19 is a seventh view showing an exemplary method for manufacturing the semiconductor device of the present invention of Example 2.

FIG. 20 is an eighth view showing an exemplary method for manufacturing the semiconductor device of the present invention of Example 2.

FIG. 21 is a ninth view showing an exemplary method for manufacturing the semiconductor device of the present invention of Example 2.

FIG. 22 is a tenth view showing an exemplary method for manufacturing the semiconductor device of the present invention of Example 2.

FIG. 23 is an eleventh view showing an exemplary method for manufacturing the semiconductor device of the present invention of Example 2.

FIG. 24 is a twelfth view showing an exemplary method for manufacturing the semiconductor device of the present invention of Example 2.

FIG. 25 is a thirteenth view showing an exemplary method for manufacturing the semiconductor device of the present invention of Example 2.

FIG. 26 is a fourteenth view showing an exemplary method for manufacturing the semiconductor device of the present invention of Example 2.

FIG. 27 is a fifteenth view showing an exemplary method for manufacturing the semiconductor device of the present invention of Example 2.

FIG. 28 is a sixteenth view showing an exemplary method for manufacturing the semiconductor device of the present invention of Example 2.

FIG. 29 is a seventeenth view showing an exemplary method for manufacturing the semiconductor device of the present invention of Example 2.

FIG. 30 is an eighteenth view showing an exemplary method for manufacturing the semiconductor device of the present invention of Example 2.

FIG. 31 is a nineteenth view showing an exemplary method for manufacturing the semiconductor device of the present invention of Example 2.

FIG. 32 is a twentieth view showing an exemplary method for manufacturing the semiconductor device of the present invention of Example 2.

FIG. 33 is a twenty first view showing an exemplary method for manufacturing the semiconductor device of the present invention of Example 2.

FIG. 34 is a schematic view showing a conventional semiconductor device.

### DESCRIPTION OF THE PREFERRED EMBODIMENTS

### Examples

Hereinafter, the semiconductor device of the present invention and the method for manufacturing the semiconductor device will be described with reference to Examples, which however shall not be construed as limiting the scope of this invention.

### Example 1

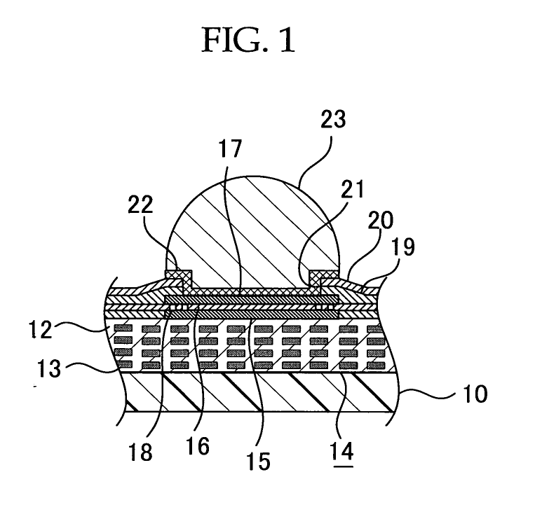

The First Example of the semiconductor device of the present invention is shown in FIG. 1. In the semiconductor device as shown in FIG. 1, an interlayer insulating film 12 made of, for example, polyimide resin and an interconnection layer 14 made of a multilayered interconnection 13 are formed over a silicon wafer 10 which serves as the foregoing semiconductor substrate. A first conductive layer 15 made of Al pad is formed over the interconnection layer 14 and an interlayer insulating film 16 made of polyimide resin and/or epoxy resin, etc. is formed over the first conductive layer 15. A second conductive layer 17 made of Al pad is formed over the interlayer insulating film 16. The second conductive layer 17 and the first conductive layer 15 are electrically connected by a number of vias 18 which are vertically disposed in the vicinity of an outer periphery of the first and the second conductive layers 15 and 17. Moreover, the vicinity of an outer periphery of the second conductive layer 17 is coated with a first resin film 19 (cover film) made of SiO₂ and the first resin film 19 is coated with a second resin film 20 (cover film) made of polyimide resin. A barrier metal layer 22 made of Ni is formed over a surface of the second conductive layer 17 which is exposed from an opening 21 of the first and the second resin films 19 and 20.

A solder ball 23 (bump), the foregoing external terminal is formed over the barrier metal layer 22 and an external terminal (solder ball 23) and the second conductive layer 17 are electrically connected to each other through the barrier metal layer 22.

Because the first conductive layer 15 and the second conductive layer 17 are disposed in the semiconductor device of Example 1, the strength of the conductive layer is increased. Therefore, it is possible to diffuse stress and appropriately prevent peeling off of conductive layers or the interconnection layer 14, which is below the conductive layer, even if stress is added to the conductive layers due to thermal stress generated when the solder ball 23 is pressurized or heated during packaging, and thermal stress caused by welding to the opposite substrate with pressure. The semiconductor device of the present invention is not particularly limited and may be selected accordingly and it is applicable for semiconductor chips in general and it is especially suitable for wafer-level packaging, for example.

In the semiconductor devices in Example 1 and other Examples to be described later, the foregoing semiconductor substrate is not limited to the foregoing silicon wafer and can be appropriately selected from insulating substrates (e.g., glass epoxy substrates, polyester substrates, polyimide substrates, bismaleimide-triazine resin substrates, thermosetting polyphenyleneether substrates, fluorine resin substrates, ceramic substrates, copper clad laminates, and resin coated copper (RCC) foil substrates), depending on the manufacturing conditions and use conditions.

Furthermore, the first and the second conductive layers 15 and 17 are not particularly limited and the constituent material, shape, structure, size, thickness and the like can be appropriately determined depending on the intended purpose.

The preferred examples of the material for the first and the second conductive layers 15 and 17 other than Al include Ni and Cu.

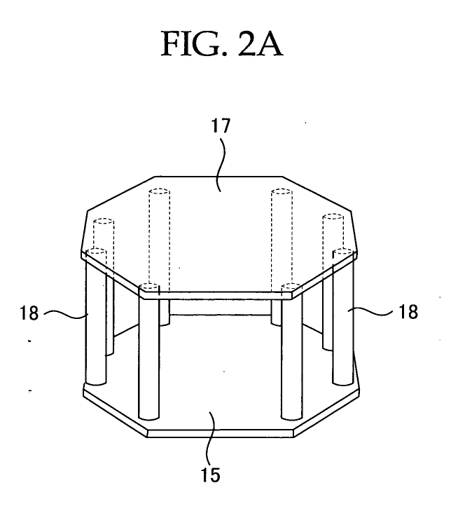

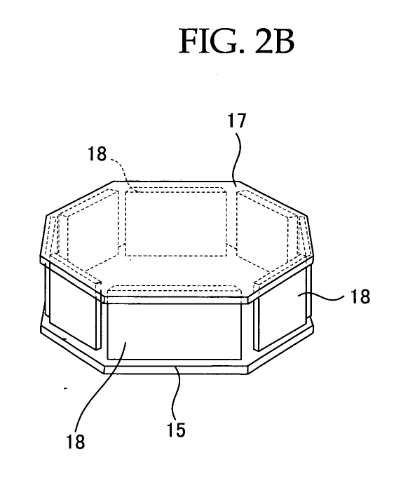

The first and the second conductive layers 15 and 17 may have hexagonal shapes as shown in FIG. 2A, triangular, square, pentagonal, heptagonal or more polygonal shapes or circular and elliptical shapes.

The thickness of the first and the second conductive layers 15 and 17 is preferably 0.5 μm to 6 μm and more preferably 1 μm to 2 μm. When the thickness is less than 0.5 μm, strength of the conductive layer becomes low and the conductive layer may be peeled off because of the general stress due to differences in degree of thermal expansion during packaging, etc. When it is more than 6 μm, flatness may be impaired or interlayer insulating films may be destroyed because of too much strength of the conductive layer itself.

The interlayer insulating films 12 and 16 are not particularly limited; the constituent material, shape, structure, size, thickness and the like can be appropriately determined depending on the intended purpose. The interlayer insulating films 12 and 16 may be made either of insulating inorganic materials or insulating organic materials. However, insulating organic materials are preferable in terms of excellent adhesion with the first resin film 19.

The insulating inorganic materials are not particularly limited and can be appropriately selected depending on the intended purpose. For example, SiN, SiO₂ and the like can be suitably adopted if the foregoing semiconductor substrate is a silicon wafer.

The insulating organic materials are not particularly limited and can be appropriately selected depending on the intended purpose; those with low permittivity and high heat resistance are preferable. In addition to the foregoing polyimide resins, polyamide resins, epoxy resins, polybenzoxazole resins, benzocyclobutene resins and the like can be suitably adopted. These resins may be used singly or in combination. For the materials of the interlayer insulating film used in wafer-level package, polyimide resins, polyamide resins, epoxy resins and the like are preferable in view of their excellent heat resistance, handling ability, and quality performance in wafer processes.

The thickness of the interlayer insulating film 16 disposed between the first and the second conductive layers 15 and 17 is not particularly limited and can be appropriately determined depending on the intended purpose; when used as an interlayer insulating film in wafer-level package, the thickness of the interlayer insulating film 16 is preferably 2 μm to 20 μm and more preferably 5 μm to 15 μm. If the thickness is less than 2 μm, the interlayer insulating film 16 itself becomes brittle, and stress due to thermal stress may cause damages to the interlayer insulating film 16 and conductive layers may be peeled off. Whereas if the thickness of the interlayer insulating film 16 is more than 20 μm, too much stress in the interlayer insulating film itself may lead to destruction of the package.

The first and the second resin films 19 and 20 are not particularly limited; the constituent material, shape, structure, size, thickness and the like can be appropriately determined depending on the intended purpose. The first and the second resin films 19 and 20 preferably serve as a cover film for protecting the second conductive layer 17.

The materials for the first and the second resin films 19 and 20 are not particularly limited and can be appropriately determined depending on the intended purpose; suitable examples thereof include, in addition to polyimide resins, polyamide resins, epoxy resins, polybenzoxazole resins and benzocyclobutene resins, for their insulation properties, low permittivity and high heat resistance. These resins may be used singly or in combination. For the materials of the resin film used in wafer-level package, polyimide resins, polyamide resins, epoxy resins and the like are preferable in terms of their excellent heat resistance, handling ability, and quality performance in wafer processes.

The first resin film 19 is preferably made of the same material as the interlayer insulating film 16. In this case, the adhesion between the interlayer insulating film 16 and the first resin film 19 is increased, suppressing the peeling off of the end of the opening 21 in the resin film 19.

The second resin film 20 is preferably formed of polyimide resins in terms of excellent insulation properties and heat resistance.

The thickness of the resin films 19 and 20 is not particularly limited and can be appropriately determined depending on the intended purpose; when used as a cover film in wafer-level package, the thickness of the resin films 19 and 20 can be appropriately determined in light of the thickness of the first and the second conductive layers 15 and 17. The thickness of the resin films 19 and 20 is preferably about 0.5 μm to 20 μm when the thickness of the conductive layers 15 and 17 is 0.5 μm to 6 μm. If the thickness of the resin films 19 and 20 is less than 0.5 μm, the resin films 19 and 20 themselves become brittle, and stress due to the difference in the degree of thermal expansion between the conductive layers 15 and 17 and resin films 19 and 20 may cause cracks in the resin films 19 and 20. Whereas if the thickness of the resin films 19 and 20 is more than 20 μm, film stress of the resin films 19 and 20 increases and adhesion with the conductive layers 15 and 17 may be lowered.

The vias 18 are not particularly limited; the constituent material, shape, structure, size, thickness and the like can be appropriately determined depending on the intended purpose.

The positions where the vias 18 are arranged are not particularly limited and may be selected accordingly. The vias 18 may be arranged vertically in the vicinity of an outer periphery of the first and the second conductive layers 15 and 17 or in the vicinity of the center of the first and the second conductive layers 15 and 17. By forming vias 18, not only the first and the second conductive layers are electrically connected but their durability to stress can also be enhanced by the support provided from the vias 18.

It is possible to increase the strength for supporting the conductive layers 15 and 17 as well as to diffuse stress uniformly by vertically arranging a number of the vias 18 of approximately the same magnitude at approximately regular intervals. By this, preventive effect for peeling off of the first and the second conductive layers 15 and 17 can be enhanced.

The shape of the vias 18 has preferably a columnar shape with the bottom surface having a circular shape as shown in FIG. 2A. Moreover, the vias 18 may have a columnar shape with the bottom surface having an elliptical shape, or a prismatic shape with the bottom surface having a triangular, square, pentagonal or more polygonal shape.

Also, as shown in FIG. 2B, plate-like vias 18 may be vertically disposed as wall in the vicinity of an outer periphery of the conductive layers 15 and 17.

The preferred materials for the barrier metal layer 22 other than Ni include Cu, Cu—Ni and Ti—Cu.

Hereinafter, an exemplary method for manufacturing the semiconductor device of the present invention of Example 1 as shown in FIG. 1 will be explained referring to figures. A general manufacturing process of silicon wafer is used for the manufacture of the semiconductor device of Example 1.

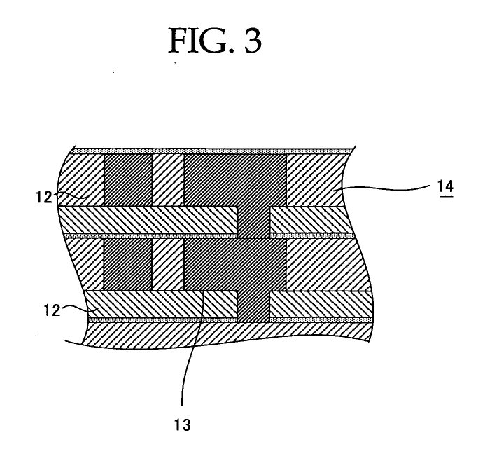

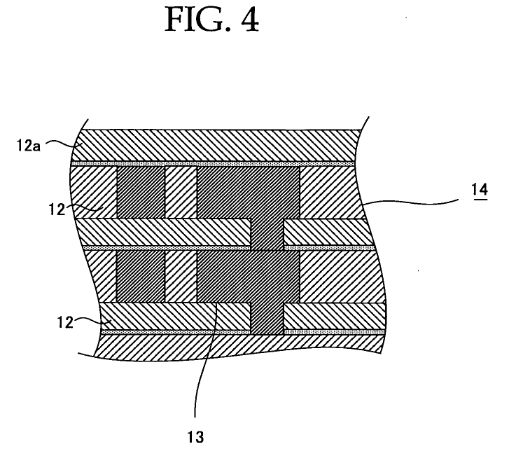

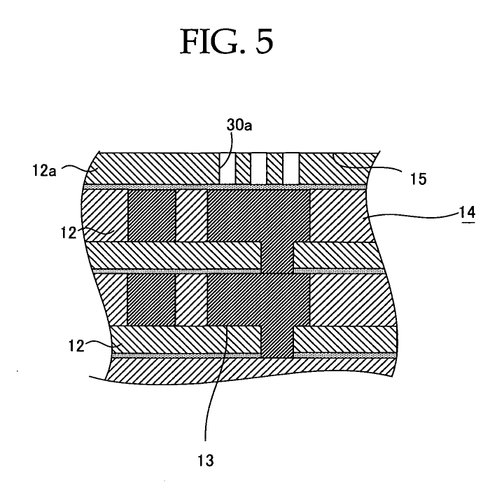

First, as shown in FIG. 3, an interconnection layer 14 containing an interlayer insulating film 12 and a multilayered interconnection 13 was formed over a silicon wafer 10 as the semiconductor substrate by the general manufacturing process. An interlayer insulating film 12a made of SiO₂ was formed by plasma CVD on the interconnection layer 14 as shown in FIG. 4. Via holes 30a were then opened in the interlayer insulating film 12a by F plasma using CF₄/CHF₃ gas as raw material and a resist layer on which via patterns are formed as a mask.

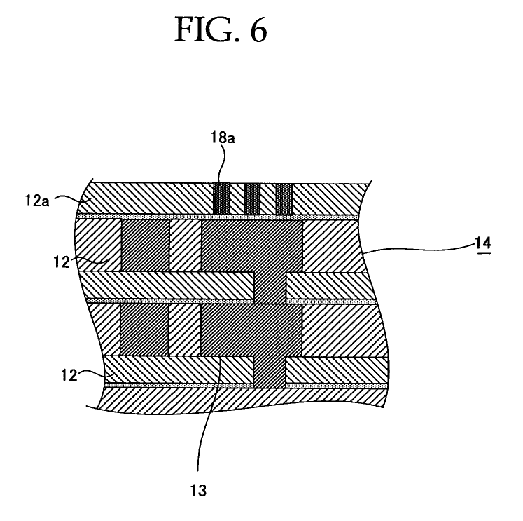

Next, conductive plugs (blankets) made of tungsten were filled in the via holes 30a by plasma CVD to form vias 18a as shown in FIG. 6.

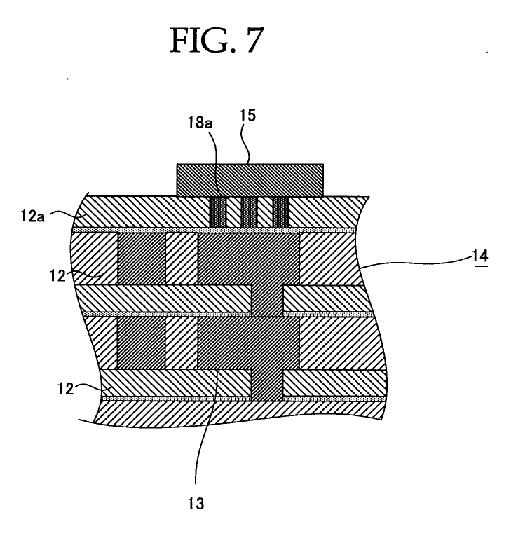

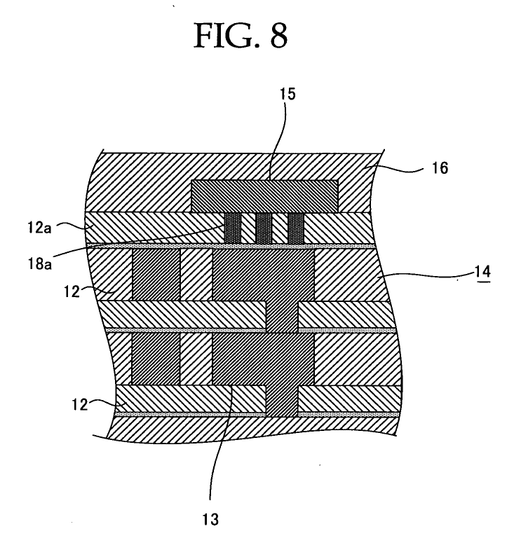

Aluminum was then deposited on the interlayer insulating film 12a by sputtering and patterned with resist to form a first conductive layer 15 in a way so that it is electrically connected to the interconnection 13 in the interconnection layer 14 through the vias 18a as shown in FIG. 7. Next, as shown in FIG. 8, the surface of the wafer was flattened by chemical mechanical polishing (CMP) after an interlayer insulating film 16 made of SiO₂ was formed by plasma CVD.

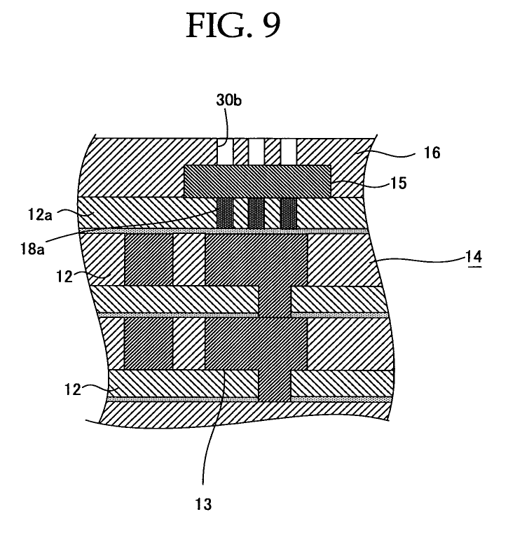

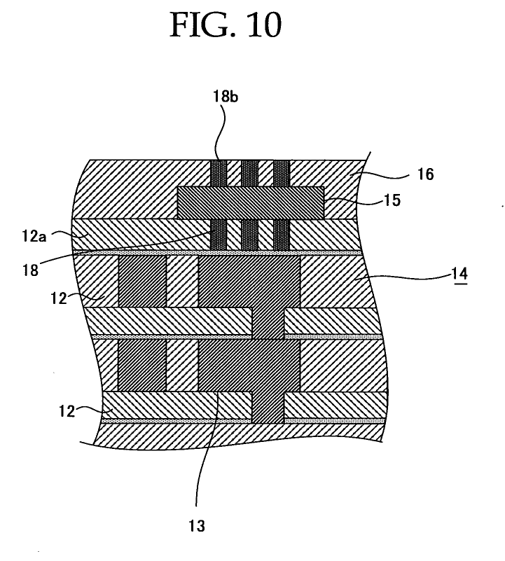

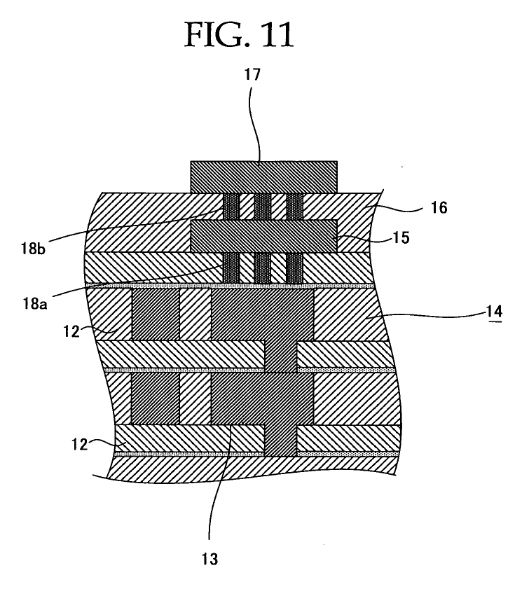

The via holes 30b were opened in the interlayer insulating film 16 as shown in FIG. 9 and filled with conductive plugs made of tungsten to form vias 18b as shown in FIG. 10 by the same procedure as described above. Aluminum was then deposited on the interlayer insulating film 16 by sputtering and patterned with resist to form a second conductive layer 17 in a way so that it is electrically connected to the first conductive layer 15 through the vias 18b as shown in FIG. 11.

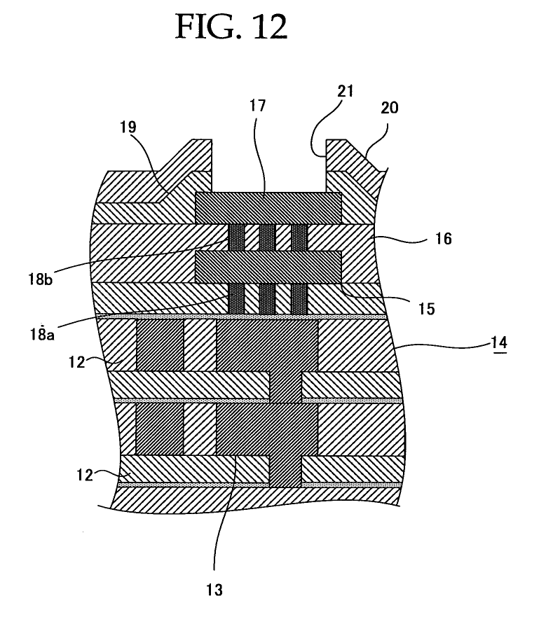

Next, a first resin film 19 made of SiO₂ was formed by plasma CVD and was coated with polyimide resin to form a second resin film 20. An Opening 21 was formed through the first and the second resin films 19 and 20 by etching as shown in FIG. 12 so as to cover the vicinity of an outer periphery of the second conductive layer 17 and expose a surface of the second conductive layer 17 from the opening 21.

A barrier metal layer 22 made of Ni was then formed in the opening 21 by evaporation. The semiconductor device shown in FIG. 1 was finally obtained by forming a solder ball 23 as an external terminal on the barrier metal layer 22, which is above the opening 21 of the first and the second resin films 19 and 20 and above the second conductive layer 17, and electrically connecting between the second conductive layer 17 and the external terminal (solder ball 23).

### Example 2

Hereinafter, an exemplary method for manufacturing the semiconductor device of the present invention of Example 2 will be explained referring to figures. The wafer-level packaging technology may be used for the manufacture of the semiconductor device of Example 2.

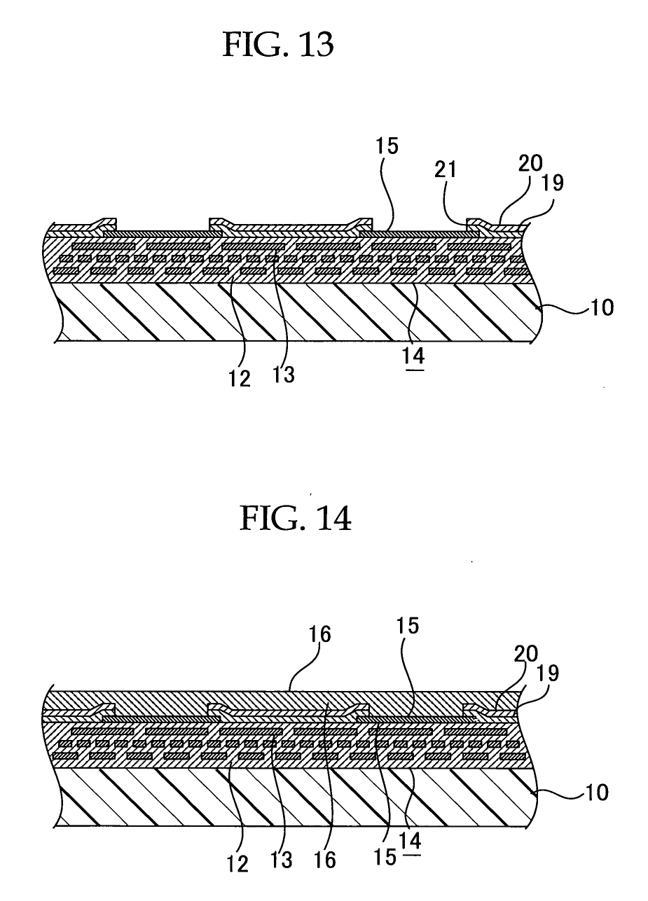

First, as shown in FIG. 13, an interconnection layer 14 containing an interlayer insulating film 12 and a multilayered interconnection 13 was formed over a silicon wafer 10 as the semiconductor substrate by the general manufacturing process for wafer as similar to Example 1. A first conductive layer 15 was formed over the interconnection layer 14 and a first resin film 19 made of SiO₂ and a second resin film 20 made of polyimide resin were formed over the first conductive layer 15 in this order. An opening 21 was formed in the first and the second resin films 19 and 20 by etching to expose a surface of the first conductive layer 15 from the opening 21.

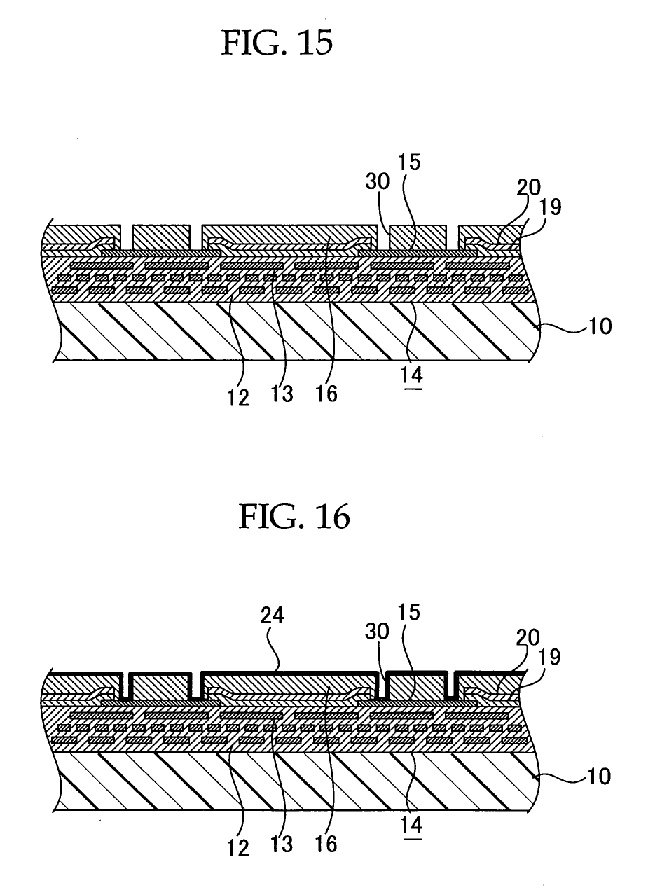

The forming steps of the second conductive layer, etc. by the interconnection technology will be explained below. As shown in FIG. 14, the first conductive layer 15 and the second resin film 20 were coated with polyimide resin and flattened by spin coating to form an interlayer insulating film 16. Next, via holes 30 were opened in the interlayer insulating film 16 by patterning as shown in FIG. 15.

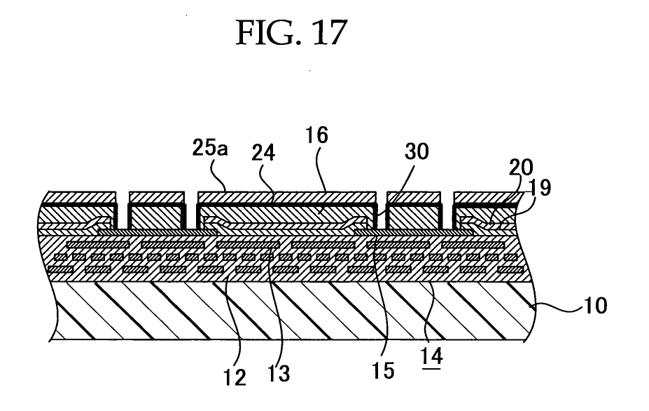

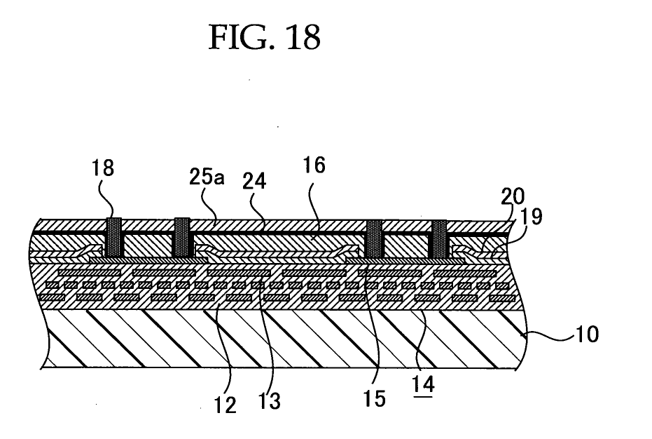

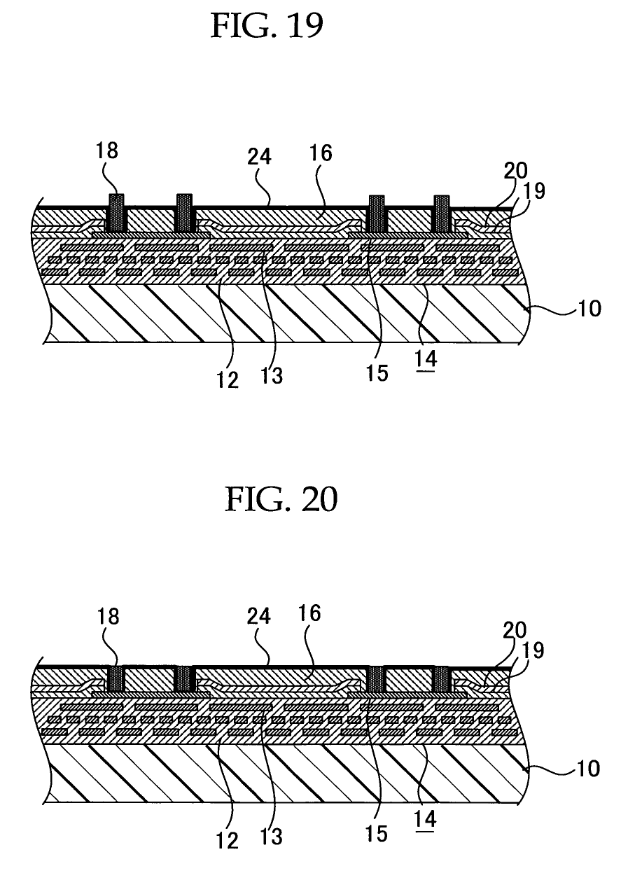

After forming a barrier metal layer 24 (shield metal layer) by applying Ti—Cu in the via holes 30 and on the interlayer insulating film 16 by vapor deposition as shown in FIG. 16, the barrier metal layer 24 was coated with plating resist and patterned to form a plating resist layer 25a on the barrier metal layer 24 except the via holes 30 as shown in FIG. 17. After forming vias 18 by filling the via holes 30 with Cu plating as shown in FIG. 18, the plating resist layer 25a was removed as shown in FIG. 19. The vias 18 were then flattened by polishing or cutting as shown in FIG. 20.

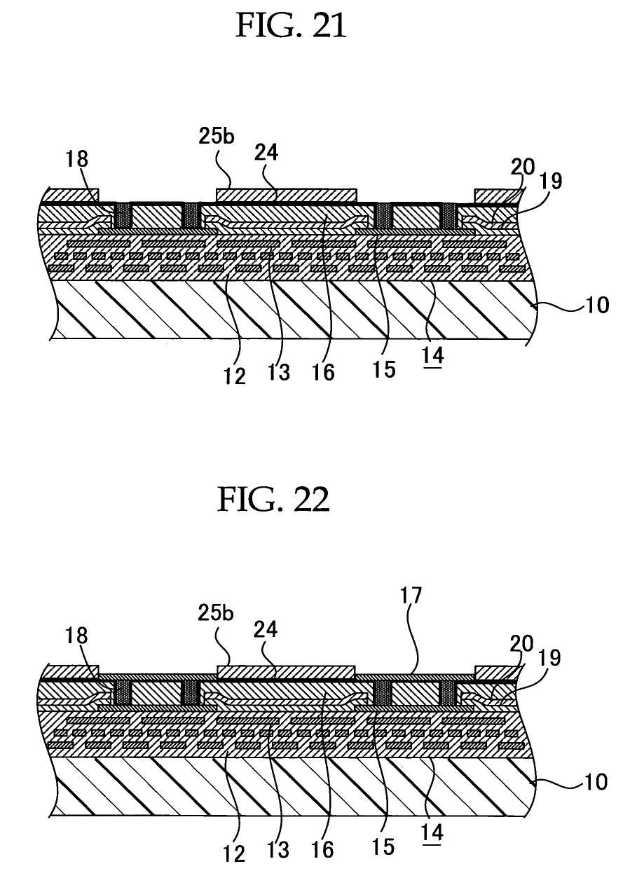

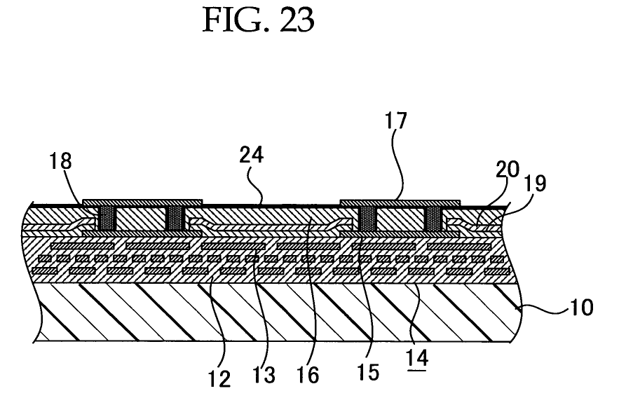

Next, a plating resist layer 25b was formed over the barrier metal layer 24 except the area where the second conductive layer 17 is formed by applying plating resist and patterning as shown in FIG. 21. After a second conductive layer 17 made of metals such as Cu—Ni was formed by vapor deposition on the area other than the area where the plating resist layer 25b was formed as shown in FIG. 22, the plating resist layer 25b was removed as shown in FIG. 23.

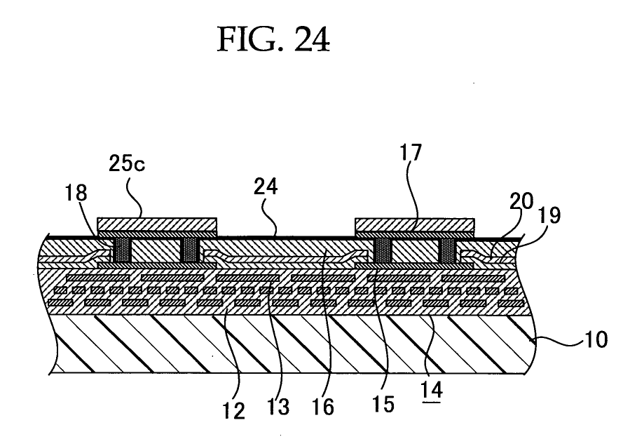

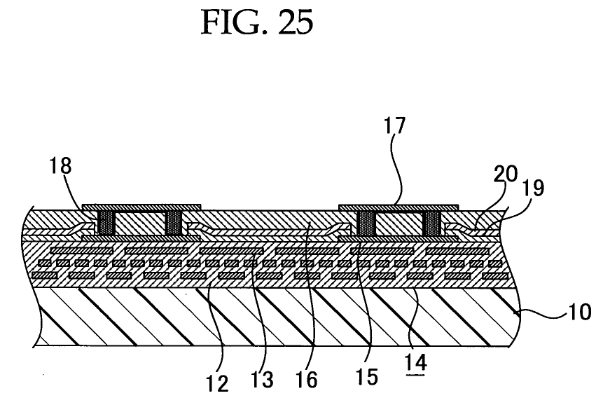

Next, a resist layer 25c was formed over the second conductive layer 17 by applying a dry film and patterning as shown in FIG. 24. The resist layer 25c was then removed as shown in FIG. 25 after the barrier metal layer 24, except the area where the resist layer 25c was formed, was removed by etching.

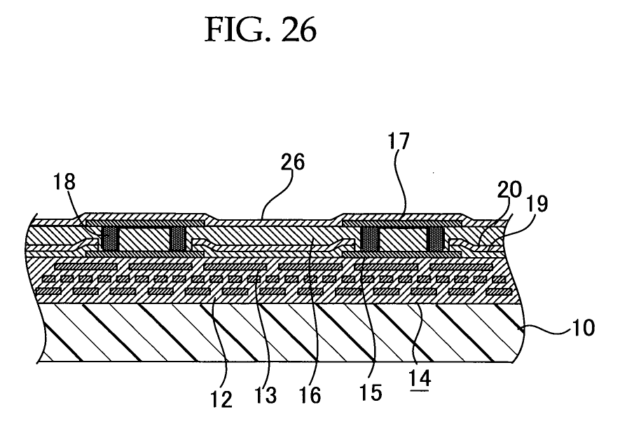

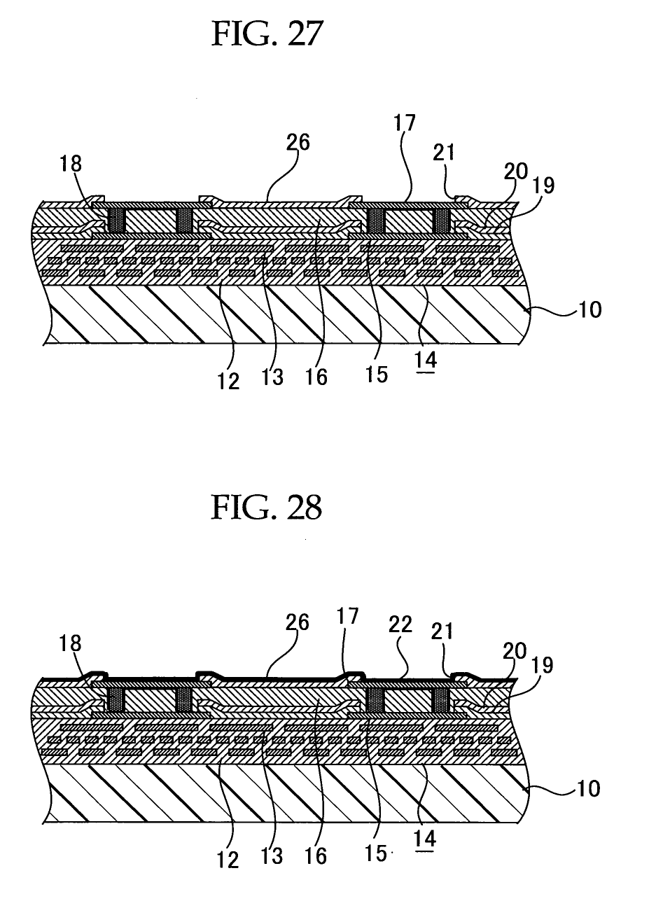

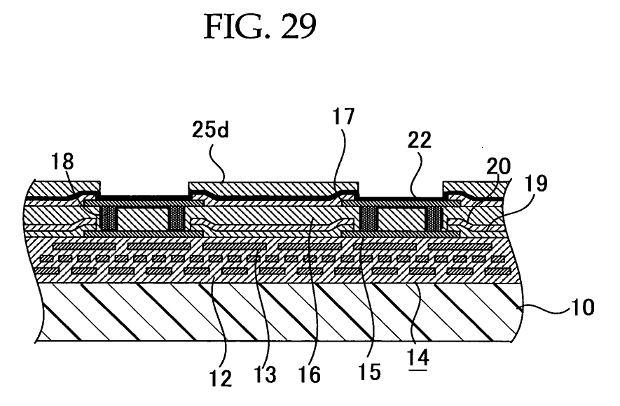

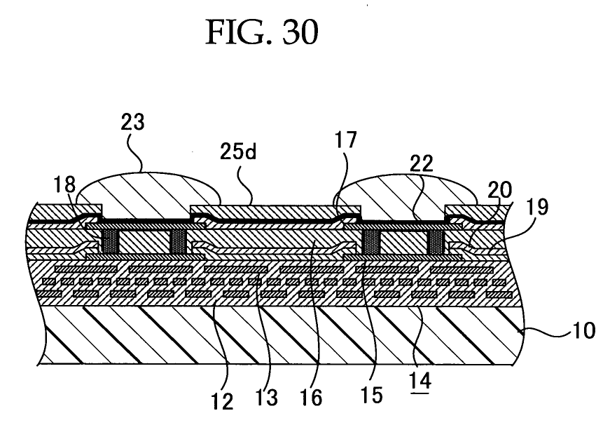

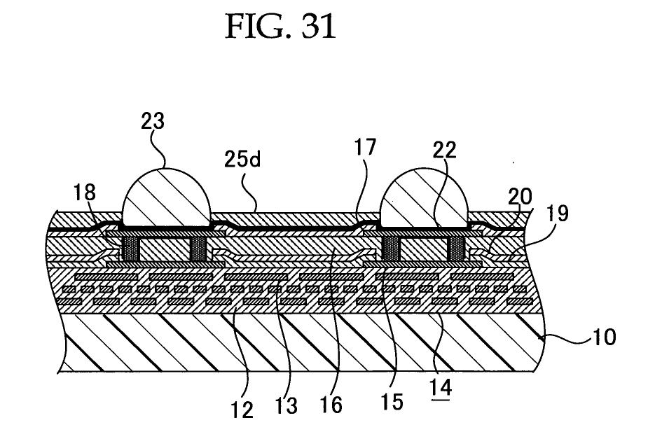

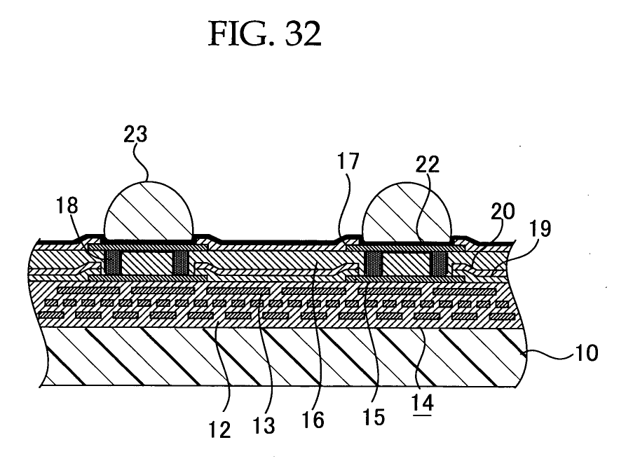

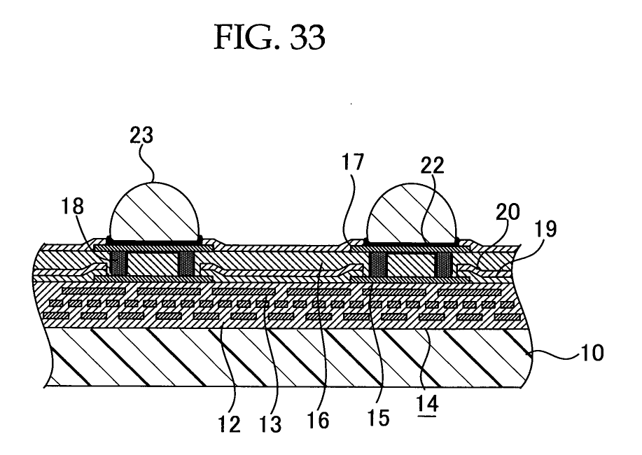

After a third resin film 26 was formed by applying polyimide resin as shown in FIG. 26, an opening 21 was formed in a third resin film 26 by patterning to expose the second conductive layer 17 from the opening 21 as shown in FIG. 27. And a barrier metal layer 22 (shield metal layer) made of Ti was formed over the surface by vapor deposition as shown in FIG. 28. The barrier metal layer 22 was coated with plating resist and a plating resist layer 25d with an opening for forming solder ball was formed over the second conductive layer 17 by patterning as shown in FIG. 29. After solder plating was applied in the openings as shown in FIG. 30, a solder ball 23 as an external terminal was formed by heating as shown in FIG. 31. By removing the plating resist layer 25d after forming the solder ball 23 as shown in FIG. 32, the semiconductor device of Example 2 was then obtained by further removing the barrier metal layer 22 around the solder ball 23 by ashing as shown in FIG. 33.

The semiconductor device of the present invention is capable of having various configurations as described below.

For example, two conductive layers of the first and second were disposed in Examples 1 and 2, however, three or more conductive layers can be disposed depending on the intended purpose or cost.

Further, another exemplary configuration may be the one having only one conductive layer. When there is only one conductive layer, it is possible to diffuse stress due to thermal stress and suppress peeling off of conductive layer, etc. by widening the surface area of the conductive layer as in the case where there are a number of conductive layers.

Similarly, when there are a number of conductive layers, it is possible to increase the degree of stress resistance and to appropriately suppress peeling off of conductive layers, etc. by widening the surface area of the uppermost conductive layer, which is the conductive layer closest to the bump (it is the second conductive layer when two conductive layers are formed and it is the third conductive layer when three conductive layers are formed), coupled with the effect of having a number of conductive layers.

### Conventional Example

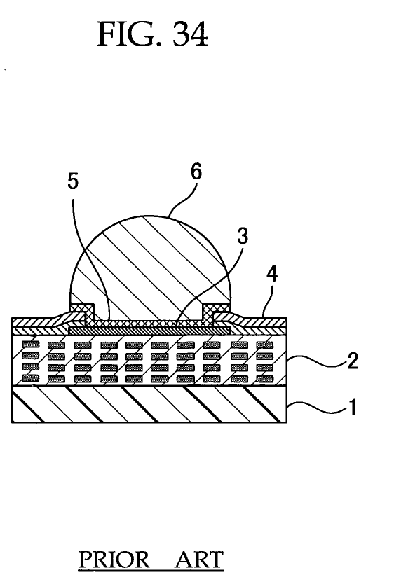

FIG. 34 shows a conventional wafer-level package.

Since the conductive layer 3 is single layered, the conductive layer 3 and the interconnection layer 2 are likely to suffer stress due to thermal stress developed during packaging, and peeling off of the conductive layer 3 and the interconnection layer 2 is likely to occur.

According to the present invention, it is possible to solve the conventional problems and to provide a semiconductor device with high performance and reliability, in which peeling off of interconnection layers and conductive layers due to thermal stress developed during packaging of a semiconductor substrate is suppressed, and thus electrical break down is prevented, and an efficient method for manufacturing the semiconductor device.

The semiconductor device of the present invention is of high performance and reliability because it suppresses peeling off of interconnection layers and conductive layers caused by thermal stress developed during packaging of a semiconductor substrate. Thus, the semiconductor device of the present invention is particularly suitable for wafer-level package.

The method for manufacturing the semiconductor device of the present invention is suitable for the manufacture of various semiconductor devices including wafer-level package, particularly for the manufacture of the semiconductor device of the present invention.

What is claimed is:

1. A semiconductor device, comprising:
a semiconductor substrate;
an interconnection layer formed over the semiconductor substrate;
a first conductive layer formed over the interconnection layer;
an interlayer insulating film formed over the first conductive layer; and
a second conductive layer formed over the interlayer insulating film so as to be electrically connected to the first conductive layer.

2. The semiconductor device according to claim 1, wherein the first conductive layer is connected to other semiconductor substrate through an external terminal.

3. The semiconductor device according to claim 1, wherein the first conductive layer and the second conductive layer are electrically connected to each other by a number of vias passing through the interlayer insulating film.

4. The semiconductor device according to claim 1, wherein the second conductive layer has wider area than the first conductive layer.

5. The semiconductor device according to claim 1, wherein the first and the second conductive layers have any one of circular, elliptical and polygonal shape.

6. The semiconductor device according to claim 3, wherein the vias are vertically disposed in the vicinity of an outer periphery of the first conductive layer and the second conductive layer.

7. The semiconductor device according to claim 6, wherein the vias have approximately the same magnitude and are vertically disposed at approximately regular intervals.

8. The semiconductor device according to claim 3, wherein the vias are in any one of columnar form, prismatic form and plate-like form.

9. The semiconductor device according to claim 1, wherein the vicinity of the outer periphery of the second conductive layer is coated with a resin film.

10. The semiconductor device according to claim 9, wherein at least two layers of the resin film is formed.

11. The semiconductor device according to claim 1, wherein the interconnection layer comprises a multilayer interconnection structure having the interlayer insulating film.

12. The semiconductor device according to claim 1, wherein the material for the first conductive layer and the second conductive layer is at least one selected from the group consisting of Al, Ni and Cu.

13. The semiconductor device according to claim 1, wherein the material for the interlayer insulating film is at least one selected from the group consisting of polyimide resins, polyamide resins, epoxy resins, polybenzoxazole resins, benzocyclobutene resins, SiN and SiO₂.

14. The semiconductor device according to claim 9, wherein the material for the resin film is at least one selected from the group consisting of polyimide resins, polyamide resins, epoxy resins, polybenzoxazole resins, benzocyclobutene resins, SiN and SiO₂.

15. The semiconductor device according to claim 2, wherein the external terminal is electrically connected to the second conductive layer through a barrier metal layer.

16. The semiconductor device according to claim 15, wherein the material for the barrier metal layer is at least one selected from the group consisting of Ni, Cu, Cu—Ni and Ti—Cu.

17. The semiconductor device according to claim 1, wherein at least one conductive layer is further disposed over the second conductive layer.

18. A method for manufacturing the semiconductor device, comprising:
forming an interconnection layer over a semiconductor substrate;
forming a first conductive layer over the interconnection layer;
forming an interlayer insulating film over the first conductive layer; and
forming a second conductive layer over the interlayer insulating film so as to be electrically connected to the first conductive layer.

19. The method for manufacturing the semiconductor device according to claim 18, wherein the forming the second conductive layer comprises forming vias which electrically connect between the first conductive layer and the second conductive layer.
